(19) United States
(12) Patent Application Publication
(10) Pub. No.: US 2025/0081355 A1
(43) Pub. Date: Mar. 6, 2025

(54) Methods Of Manufacture Of A Compact Phased Array Antenna

(71) Applicant: Battelle Memorial Institute, Columbus, OH (US)

(72) Inventors: Daniel G. LOESCH, Sunbury, OH (US); Jeff MINER, Newark, OH (US); Curt HUDBERG, Westerville, OH (US)

(21) Appl. No.: 18/819,080

(22) Filed: Aug. 29, 2024

Related U.S. Application Data
(60) Provisional application No. 63/580,160, filed on Sep. 1, 2023.

(51) Int. Cl. H05K 3/00; H01Q 1/38; H05K 3/04; H05K 3/40

(52) U.S. Cl. CPC H05K 3/0044; H01Q 1/38; H05K 3/043; H05K 3/4038; H05K 2203/0228

(57) ABSTRACT

The present disclosure teaches subtractive methods, additive methods, and hybrid additive/subtractive methods of forming a compact phased array antenna. In ore embodiment, the present disclosure provides a method of forming a compact phased array antenna that includes milling a plurality of spaced-apart antenna elements by removing material of a multilayer printed circuit board (PCB) structure, the multilayer PCB structure including a base dielectric layer and a plurality of stacked dielectric layers laminated together to form a unitary structure; forming a plurality of via holes in the base dielectric layer and adjacent the antenna elements; and depositing conductive material on the base dielectric layer and antenna elements.

### CROSS-REFERENCE TO RELATED APPLICATIONS

The present application claims the benefit of U.S. Provisional Application Ser. No. 63/580,160, filed Sep. 1, 2023, which is hereby incorporated by reference in its entirety.

### TECHNICAL FIELD

The present disclosure relates to manufacturing methods of a compact phased array antenna.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIGS. 1-7 illustrate a subtractive manufacturing method to form a compact phased array antenna according to one embodiment of the present disclosure;

FIGS. 8-18 illustrate an additive manufacturing method to form a compact phased array antenna according to one embodiment of the present disclosure;

FIG. 19 illustrates a hybrid manufacturing method to form a compact phased array antenna according to one embodiment of the present disclosure; and

FIGS. 20 and 21 illustrate a compact phased array antenna according to another embodiment.

Although the following Detailed Description will proceed with reference being made to illustrative embodiments, many alternatives, modifications and variations thereof will be apparent to those skilled in the art.

### DETAILED DESCRIPTION

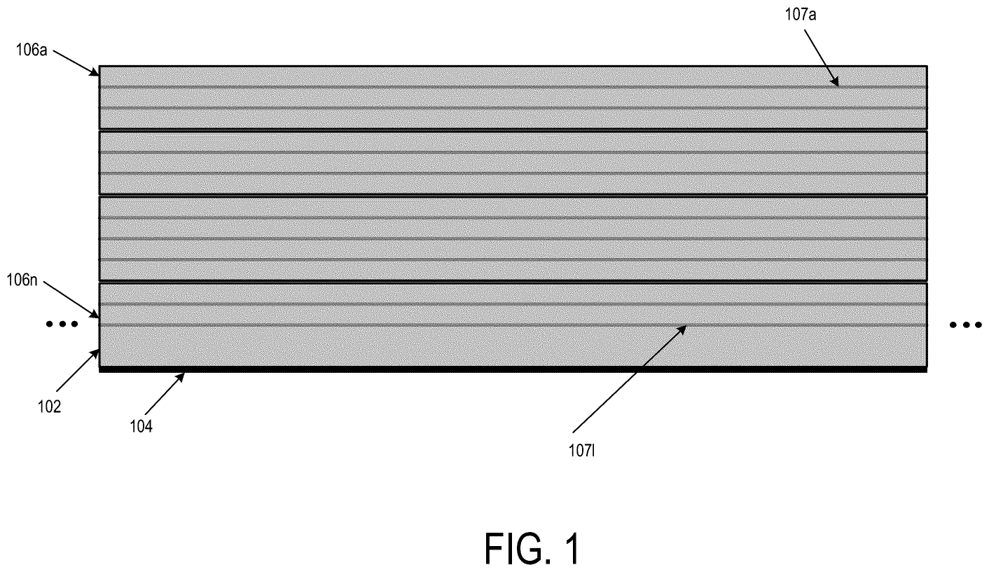

FIGS. 1-7 illustrate a subtractive manufacturing method to form a compact phased array antenna, also referred to herein as a Differential Segmented Aperture (DSA), according to one embodiment of the present disclosure. In this embodiment, a DSA antenna is formed using a multilayer Printed Circuit Board (PCB) structure. FIG. 1 illustrates a multilayer PCB that includes a base dielectric layer 102, a signal layer 104 (e.g., copper metal) formed on the underside of the base dielectric layer 102, and a plurality of stacked dielectric layers 106a . . . 106n stacked on top of each other and on top of the base dielectric layer 102. The stacked dielectric layers 106a . . . 106n and the base dielectric layer 102 may be laminated together, thus forming a unitary structure. Each of the stacked substrate layers 106a . . . 106n and 102 may have a slightly or substantially large difference between dielectric constants to allow for a dielectric gradient, for example, for a translation from the freespace impedance to the impedance used for the system's RF circuitry (not shown in this drawing) (e.g., 377 Ohms to 50 Ohms, etc.). Thus, for example, layer 106a may have a dielectric constant that is lower than the dielectric constant of layer 106j depending on, for example, impedance measurements of the overall system, balun circuitry (not shown in this drawing), desired operating frequency, etc. In addition, the dielectric constant of layers 106a through 106j may change in a linear fashion or non-linear fashion. In other embodiments, the stacked substrate layers may all have the same or substantially the same dielectric values. These many additional degrees of freedom allow DSA designs using this methodology to avoid common design compromises and provide the ability to achieve greater efficiencies than typically realized with phased arrays.

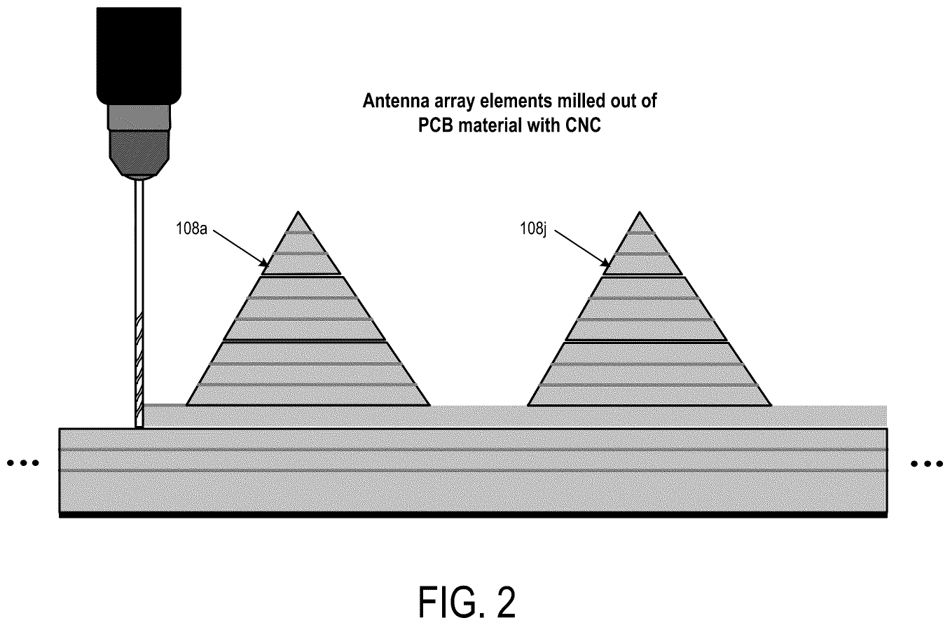

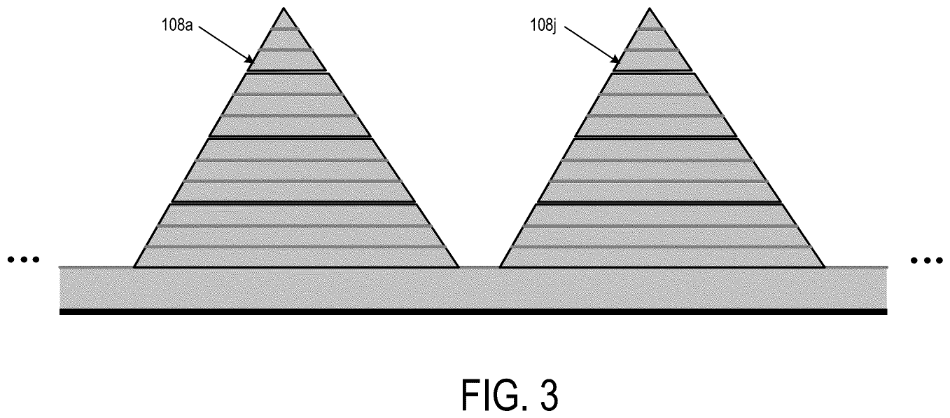

FIG. 2 illustrates forming the elements for the phased array antenna, illustrated as pyramid structures 108a . . . 108j in the stacked dielectric layers 106a . . . 106n. The pyramid structures 108a . . . 108j may be formed, for example by milling, using a CNC machine, etc., the stacked dielectric layers 106a . . . 106n to form the shapes as illustrated. It should be noted that the pyramid structures are three dimensional, rather than the two dimensional representation shown in the drawings. FIG. 3 illustrates the fully-formed pyramid structures 108a . . . 108j. Advantageously, because the stacked dielectric layers 106a . . . 106n and the base dielectric layer 102 are laminated together, the pyramid structures 108a . . . 108j are therefore laminated to the base layer 102, thus increasing the structural integrity of the DSA antenna, while decreasing manufacturing complexity. In some embodiments, the laminated layers 106a . . . 106j may be formed using PCB cores, each having a copper cladding on the top and bottom surfaces, which are laminated together using, for example, a prepreg composite layer 107a . . . , 107l (e.g., resin/fabric insulative material) between each PCB core. The typical manufacturing process for a compact phased array is to construct the antenna elements from a milled metal, then plate the elements, then affix them to the interface plane mechanically or with solder. This is an expensive and labor-intensive process and thus increases cost and manufacturing time compared to the processes described herein. The methodology and composition of the phased array described in this disclosure are significantly more efficient due to the elimination of disparate materials each requiring many unique fabrication steps, and instead provides that the entire device to be fabricated using the highly efficient, fast and cost-effective PCB process.

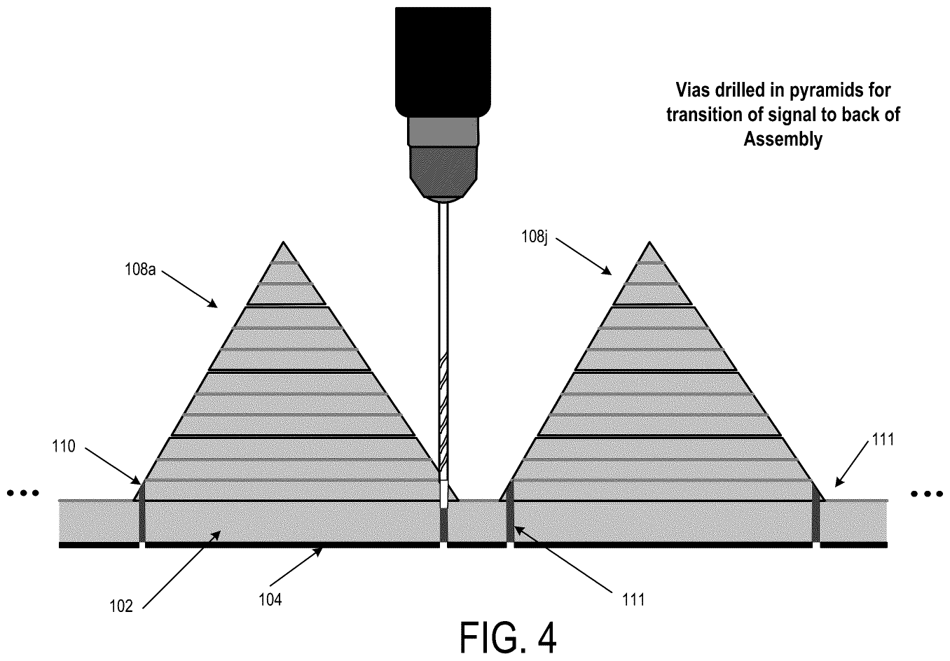

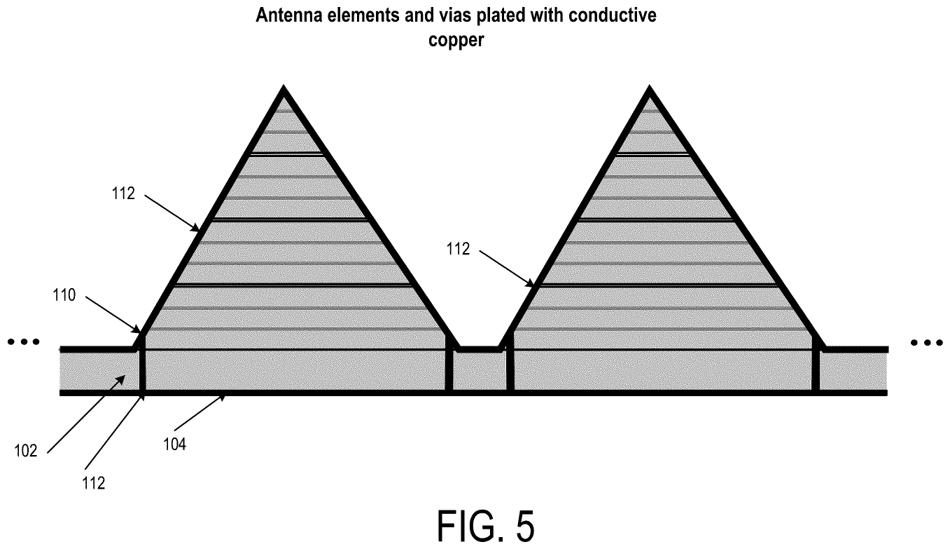

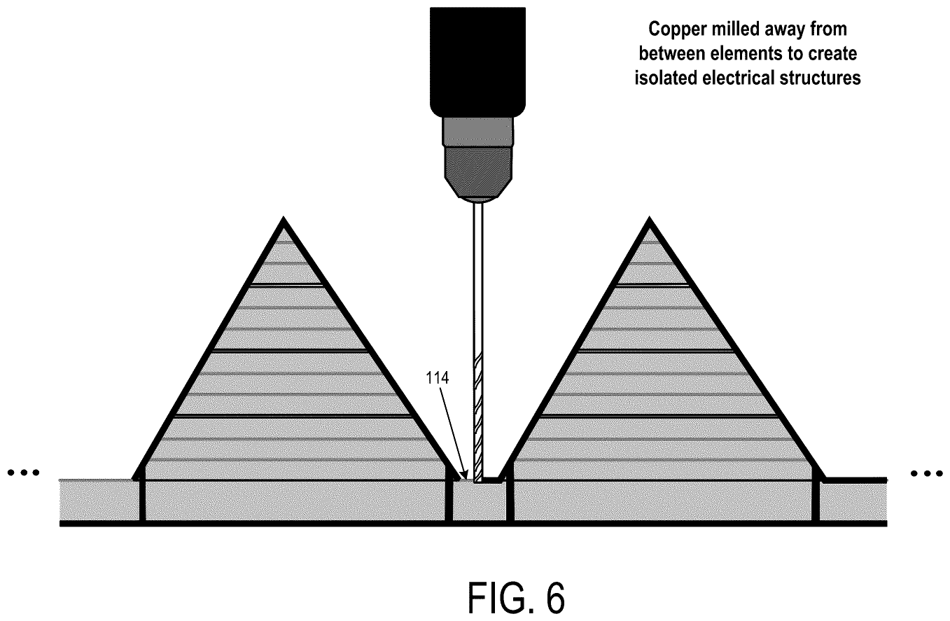

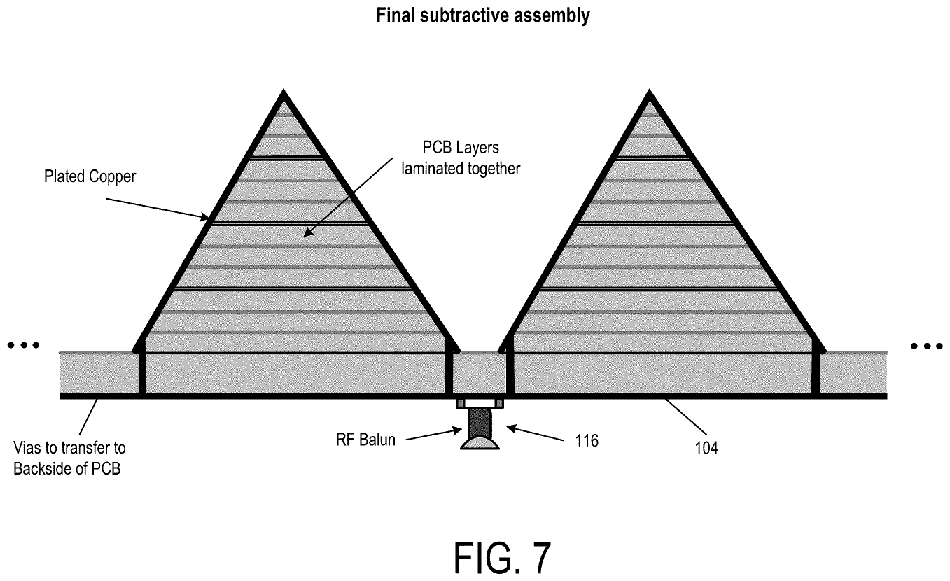

In FIG. 4, via holes 110 are machined (e.g., drilled) through the base layer 102 to the conductive layer 104. The via holes 110 are generally formed approximately adjacent to the base of the pyramid structures 108a . . . 108j, at the interface 111 between the base layer 102 and each pyramid structure 108a . . . 108j, as illustrated. In FIG. 5, the via holes 110 and the top surface of the pyramid structures 108a . . . 108j are plated with conductive material (e.g., copper, etc.), as generally shown at 112, thus forming a radio frequency (RF) transmission line between the pyramid structures 108a . . . 108j and the signal layer 104. In FIG. 6, the conductive material (e.g., copper, etc.) is removed (shown at 114) from between the pyramid structures 108a . . . 108j, creating electrically isolated pyramid structures. FIG. 7 illustrates the finished product and shows RF balun circuitry 116 coupled to the signal layer 104.

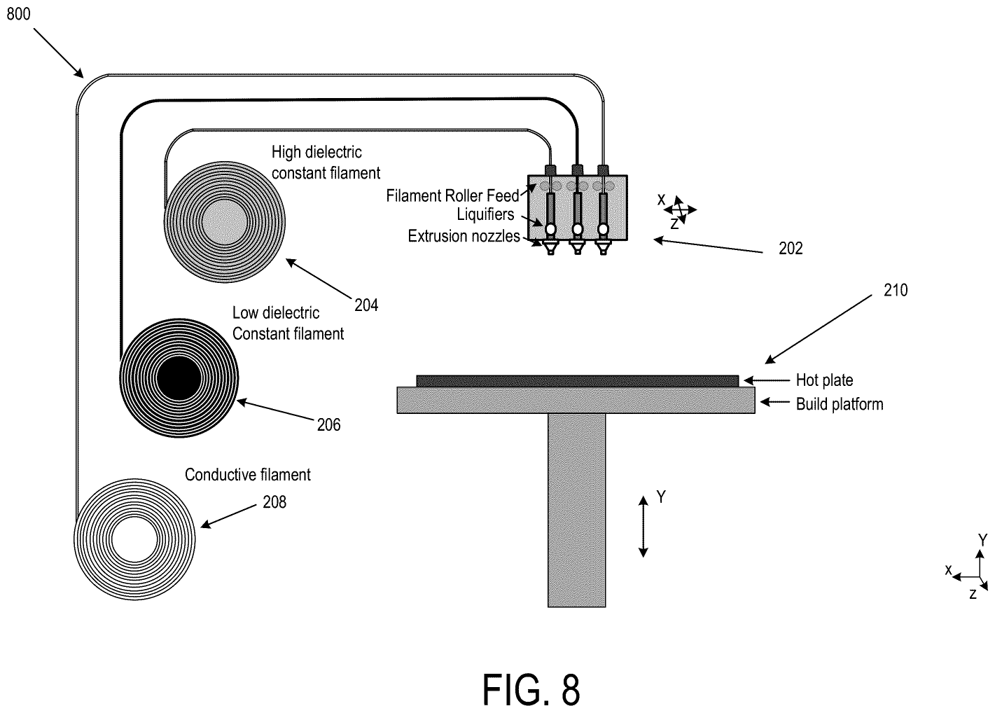

FIGS. 8-15 illustrate an additive manufacturing method to form a DSA antenna according to one embodiment of the present disclosure. The additive manufacturing processes to form a DSA antenna according to this embodiment may include, for example, fused deposition modeling (FDM) techniques and apparatus, stereolithography (SLA) techniques and apparatus, selective laser sintering (SLS) techniques and apparatus, etc. As is known, FDM techniques generally involve melting and extruding thermoplastic filaments to form various shapes/features, SLA techniques generally involve laser curing of photopolymer resins, and SLS techniques generally involve laser fusion of polymer powders.

FIG. 8 illustrates an example apparatus 800 that may be used for a fused deposition modelling (FDM) process according to the teachings herein. The apparatus 800 may include a deposition nozzle unit 202 generally configured to deposit dielectric material 204 and 206, and conductive material 208 used to create a signal layer (or signal plane). The apparatus 800 is illustrated a a generalized 3-D printing (FDM) machine, for example, an FDM machine manufactured and sold by Ultimaker, etc. As is known, the deposition nozzle unit 202 may include one or more filament roller feeds, one or more liquifiers, and one or more extrusion nozzles (each of which may have a selectable extrusion output volume/shape). While the number of dielectric materials used can vary depending upon the specific FDM equipment used, for illustrative purposes it has been shown here with two dielectric materials, a high dielectric constant material 204, and a low dielectric constant material 206. In one example embodiment, the high dielectric constant material 204 may include an extrudable polymeric material (which may include impregnated ceramic material) having a dielectric constant of, for example 1-10, and the low dielectric constant material 206 may include an extrudable polymeric material (which may include impregnated ceramic material) having a dielectric constant of, for example 1-5. In some embodiments, multiple dielectric materials and nozzles may be used to provide, for example, dielectric gradients by controlling deposition of different dielectric material on top of one another. The deposition nozzle unit 202 generally includes a number of nozzles to extrude the dielectric material and a final nozzle to extrude the conductive material. A platform and hot plate 210 are provided upon which a DSA antenna is formed, as illustrated below.

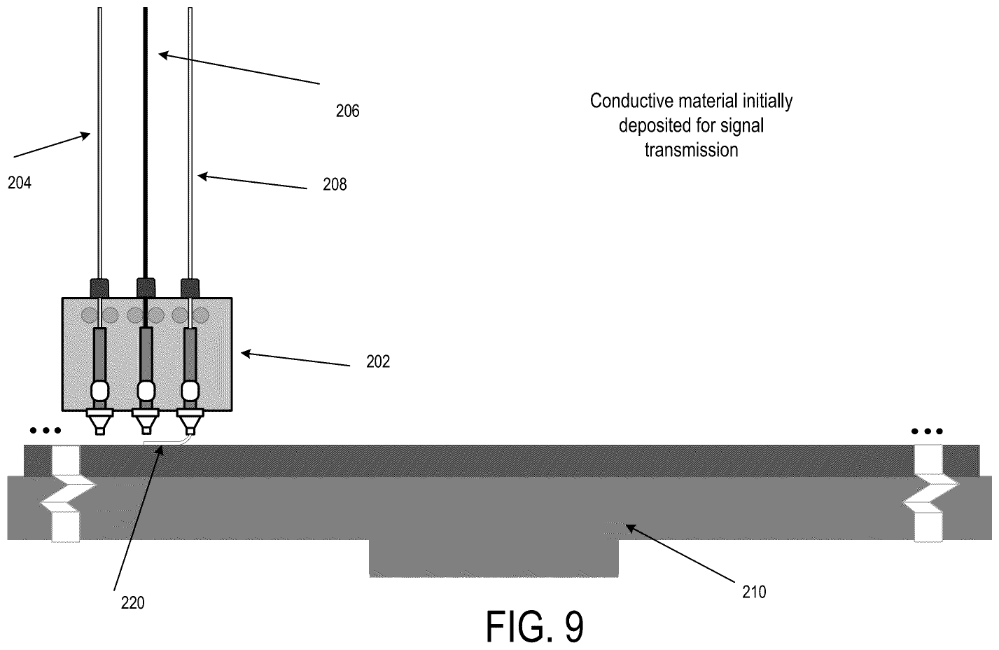

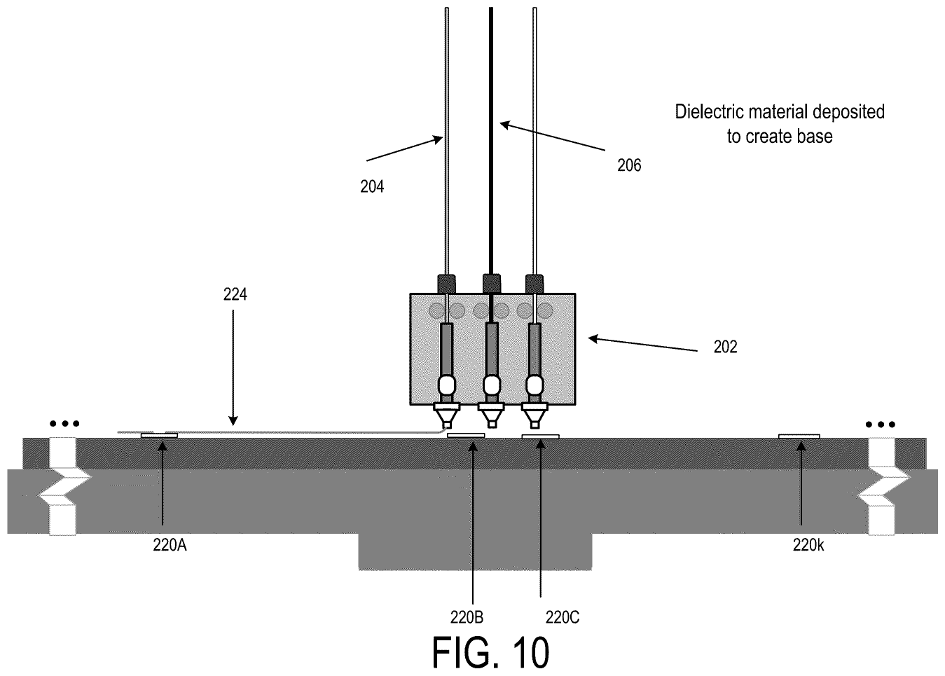

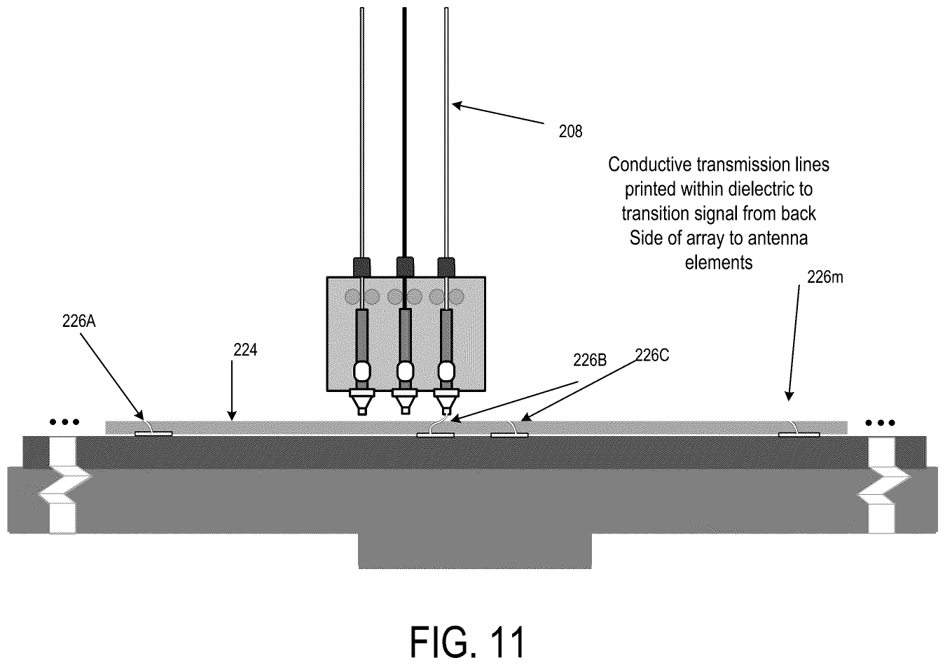

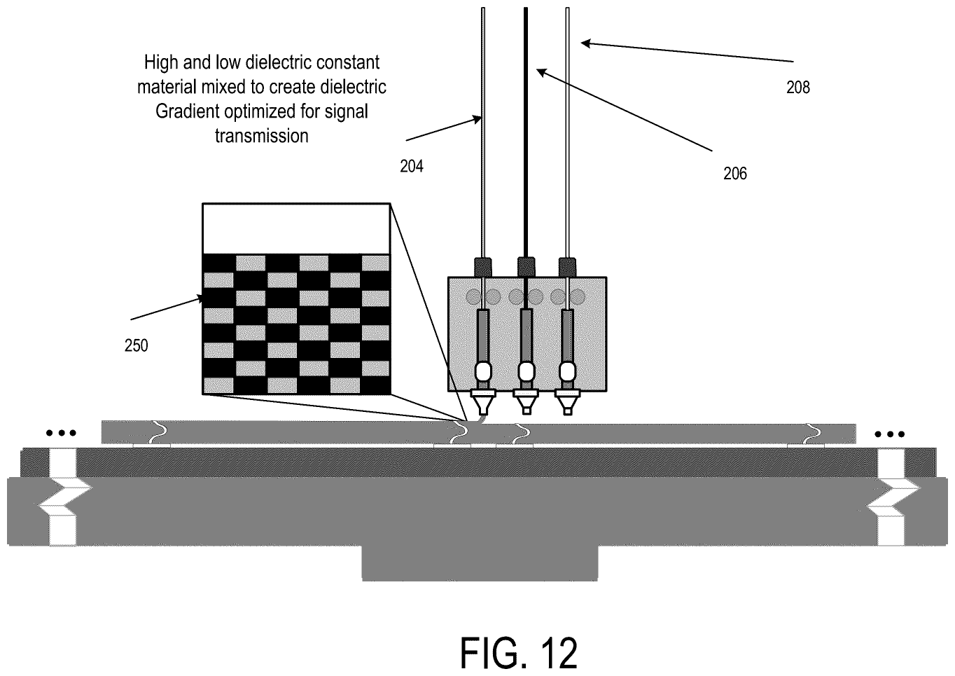

In FIG. 9 the deposition nozzle 202 is controlled to initially form a conductive layer 220 deposited on the platform/hot plate 210 using the conductive material 208. In FIG. 10, the conductive layers 220A, 220B, . . . , 220k have been formed (FIG. 9), and a dielectric material is deposited to form a base layer 224. The base layer may be formed using the high dielectric material 204, the low dielectric material 206 or any combination thereof. In FIG. 11, via lines 226A, 226B, . . . , 226m are deposited at selected locations while depositing dielectric material 208 to provide conductivity through the dielectric material 224 to a signal layer (underside of the array). As illustrated, the majority of the material deposited is dielectric and provides structural rigidity and electrical isolation between the different electrical structures in the system. The conductive material in this figure is forming the transmission lines to be used within the completed system to pass signals from the antenna elements to the baluns on the back of the base (not shown). In FIG. 12, the high dielectric material 204 and low dielectric material 206 are controllably extruded in a pattern 250 that results in a dielectric gradient. The pattern 250 is selected to provide a desired dielectric gradient for selected impedance matching, and the pattern 250 may be altered at each layer of the deposition process to provide antenna element structures having a selected gradient (e.g., 377 Ohms to 50 Ohms, etc.)

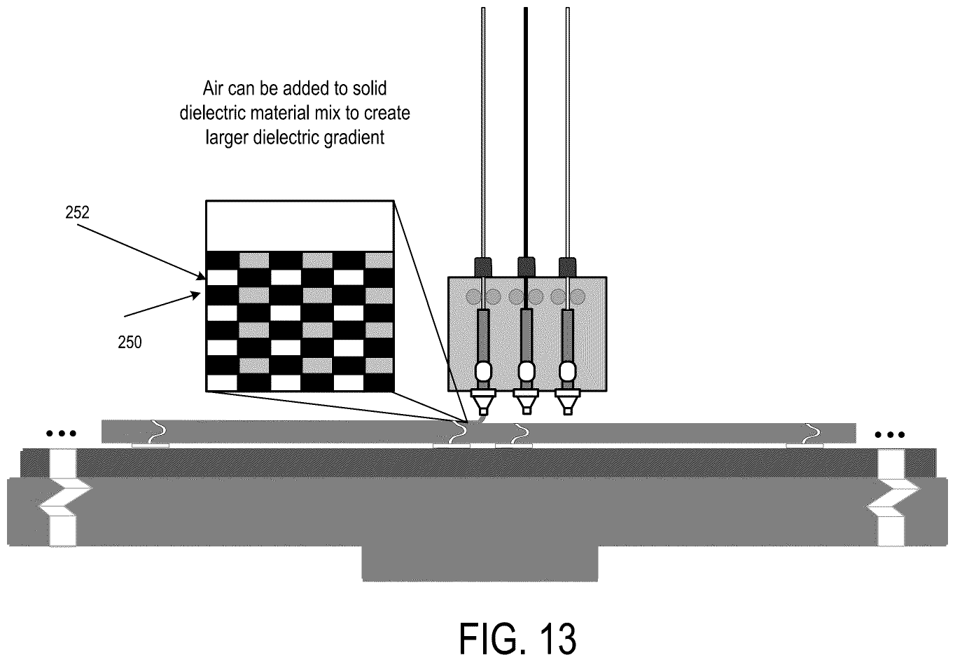

In FIG. 13, a similar composite is being constructed as in FIG. 13, except in addition to the high and low dielectric materials being used to construct the patterned composite, one or more pockets of air 252 may also added. This may allow for a lower composite dielectric constant to be generated due to the relatively low dielectric constant of air (approximately 1).

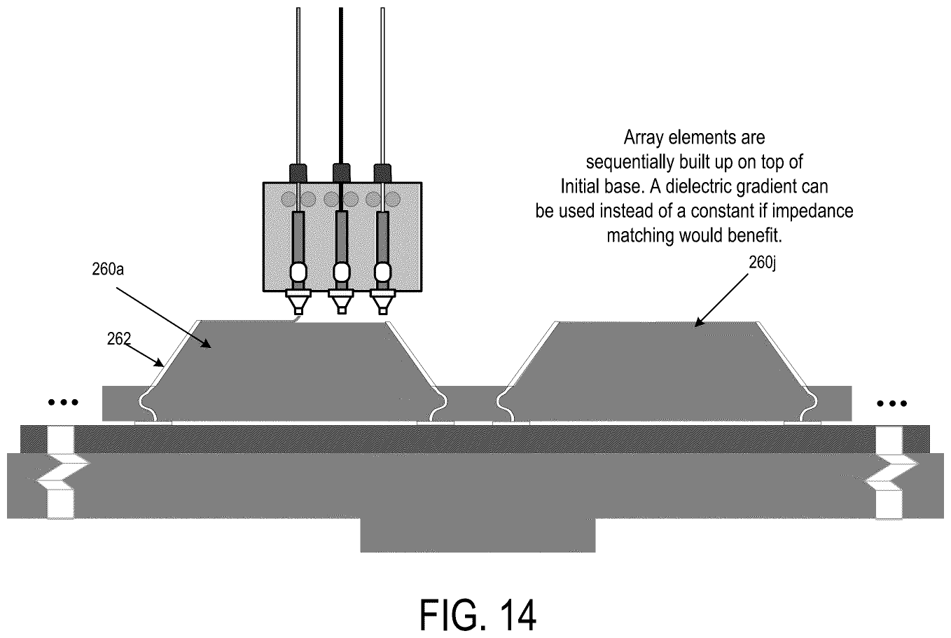

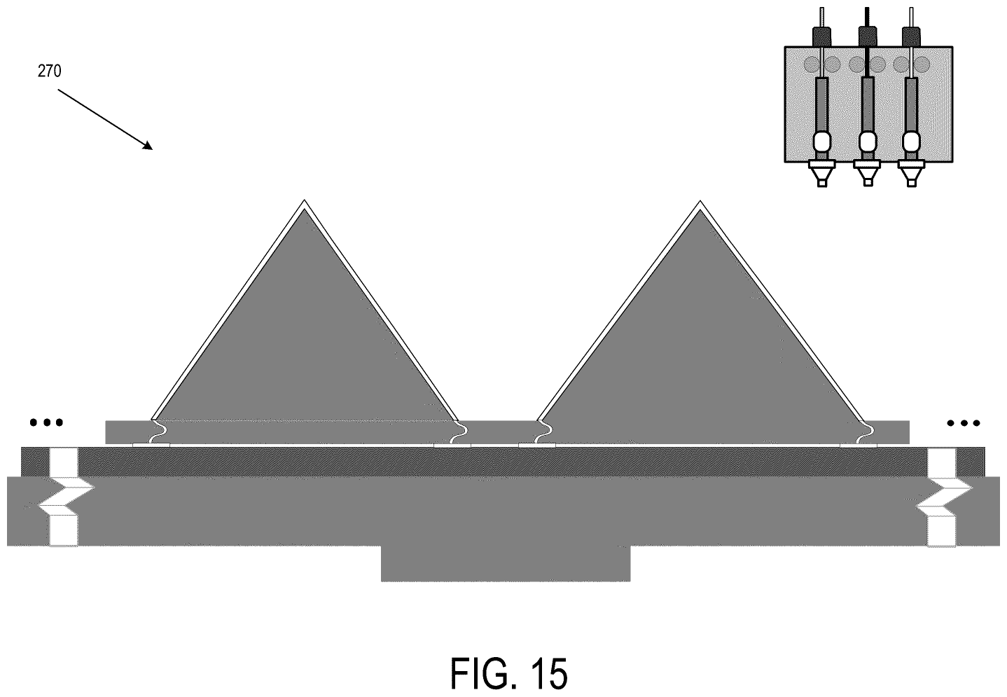

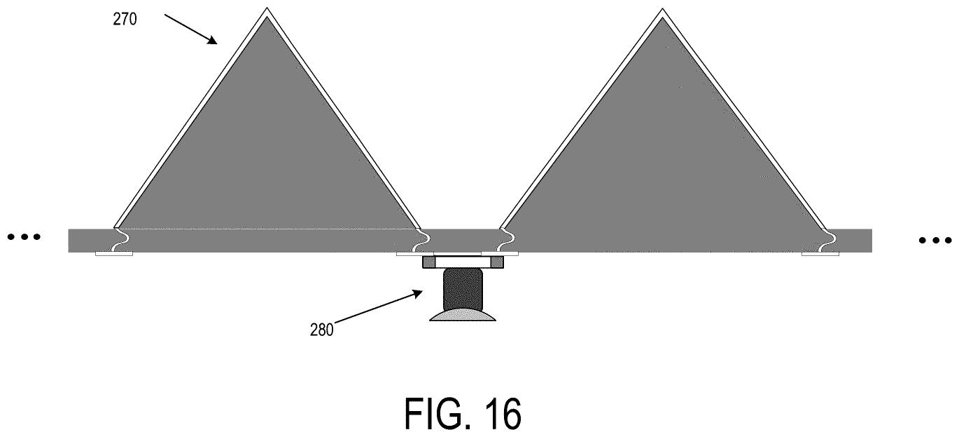

In FIG. 14, the antenna array pyramidal elements 260a . . . 260j are formed by sequentially building up layers, so that the pyramid structure has a tuned dielectric gradient, facilitating an optimized transition of electromagnetic energy from free space to the DSA. In addition, a conductive layer 262 may be deposited on the pyramid structures 260a . . . 260j, and electrically coupled to the via lines 226A, 226B, . . . , 226m, as illustrated. FIG. 15 illustrates the formed antenna structure 270. FIG. 16 illustrates the formed antenna structure 270 and also illustrates a connected balun 280.

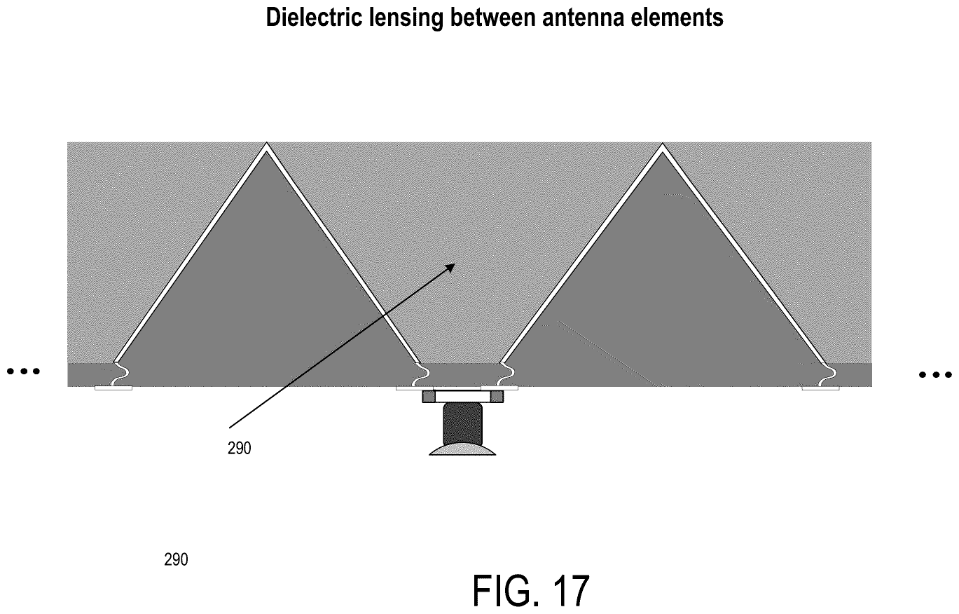

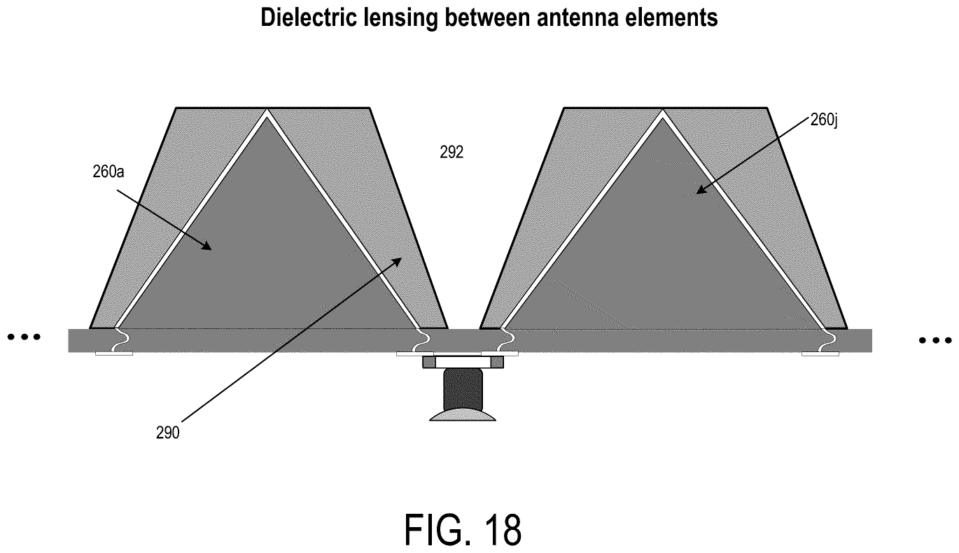

FIG. 17 illustrates a GRadient-INdex (GRIN) lens 290 constructed between the pyramidal antenna array elements. Dielectric lensing, as illustrated in FIG. 18, may provide more accurate impedance matching between free space RF signals and the electronic components of the DSA antenna as well as improvements in antenna beam patterns. The lens 290 may be formed using the deposition (additive) processes described above and may include a constant or gradient dielectric structure as described above. In FIG. 18, the dielectric lensing concept includes removing material between the pyramid structures to create an air gap 292 between pyramid structures 260a . . . 260j and to create a custom GRIN geometry. The shape of the air gap 292 may enable, for example enhanced ohmic transition between the antenna and free space (e.g., 377 to 50 ohms, etc.), and thus may be selected based on, for example, desired impedance matching, overall operating frequency of the array 270, etc.

While the foregoing description of FIGS. 8-18 illustrate a DSA antenna formed using an FDM process, in other embodiments, the DSA antenna may be formed using, for example, laser stereolithography (SLA) processes, selective laser sintering (SLS) processes, etc.

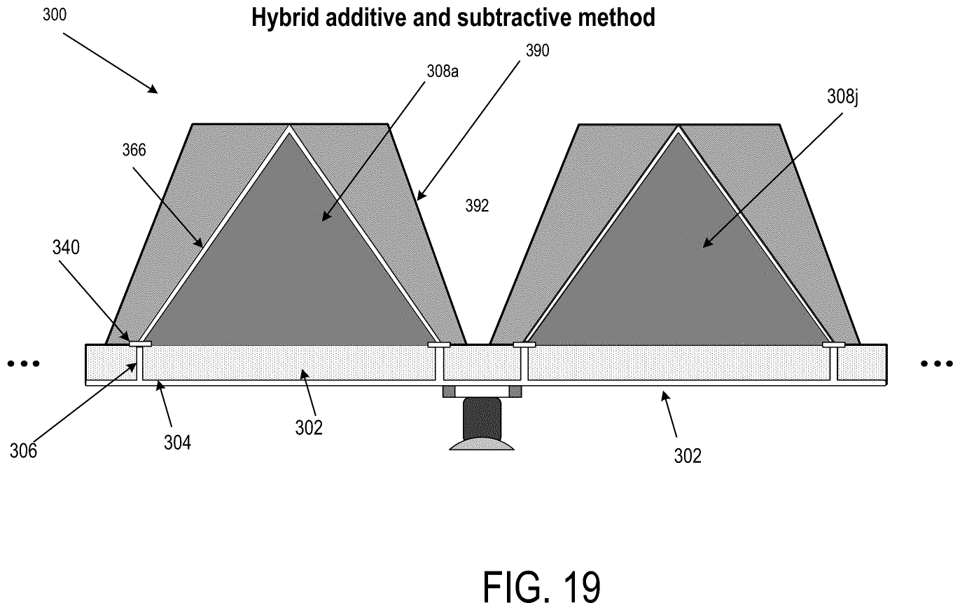

FIG. 19 illustrates a hybrid manufacturing method to form a differentially segmented aperture antenna 300 according to another embodiment of the present disclosure. In this embodiment, the base layer 302 may be formed of a printed circuit board (PCB) material, and the base layer 302 may include a conductive layer 304 formed on the bottom surface of the base layer 302. Via holes 306 may be formed within the PCB using subtractive (e.g., milling) processes, as described above with reference to FIGS. 1-7. The via holes 306 may be filled with a conductive material, as described above. Conductive material may be deposited over the via holes 306 to form a plurality of copper pads 340. A plurality of pyramid structures 308a . . . 308j may be formed on the base layer 302 using the additive process described above. The plurality of pyramid structures 308a . . . 308j may each be formed having a dielectric gradient, as described above. Conductive material 366 may be formed on the plurality of pyramid structures 308a . . . 308j using the additive and subtractive processes described above. Dielectric lensing material 390 may be deposited between the plurality of pyramid structures 308a . . . 308j (using the additive processes of the dielectric material described above), and a portion of the lensing material 390 may be removed to form a gap 392, as described above.

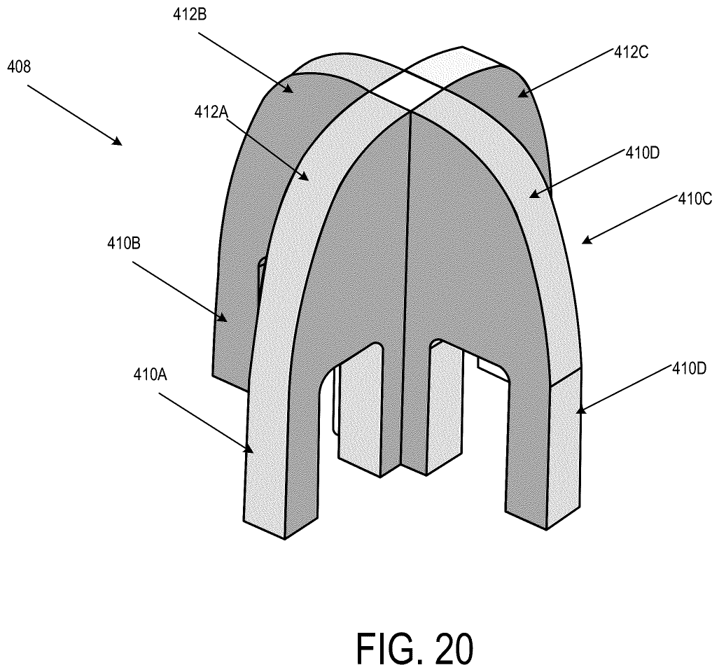

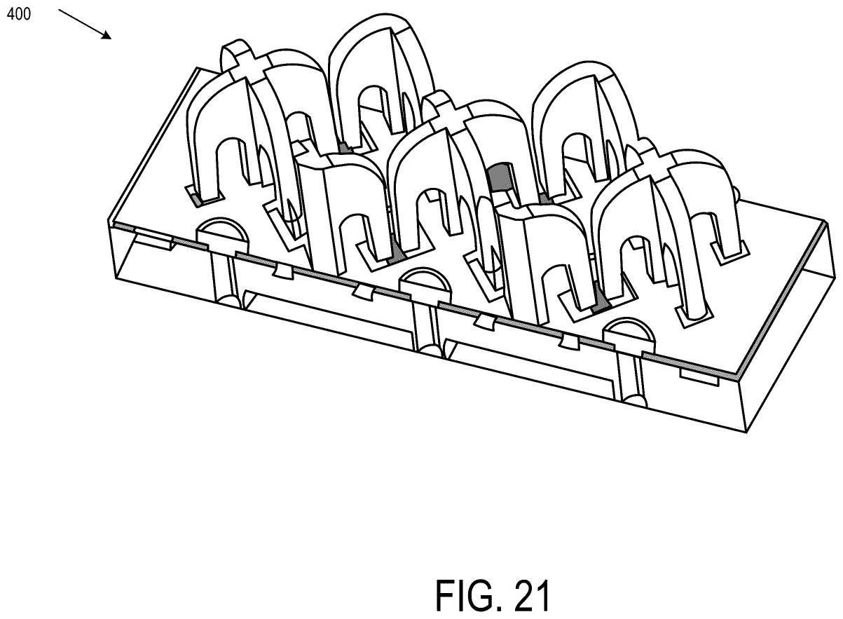

FIGS. 20 and 21 illustrate a compact phased array antenna according to another embodiment. In this embodiment, and as shown in FIG. 20, each antenna element 408 is formed to have a domed structure. The domed structured may be formed by four leg elements 410A, 410B, 410C and 410D each having a straight lower portion (and generally parallel to one another) and an arcuate upper portion 410A, 412B, 412C and 412D, respectively. The arcuate upper portions 410A, 412B, 412C and 412D, arch inwardly towards an opposing leg element, thus forming a “domed” upper portion of the antenna element 408. The antenna element 408 may be formed using the additive processes described above, i.e., by building the leg elements 410A, 410B, 410C and 410D and the arcuate upper portions 410A, 412B, 412C and 412D by successive deposition of the conductive material (e.g., copper, etc.). FIG. 2 illustrates an array 400 formed of the antenna elements 408. The array 400 may be formed using the additive and/or hybrid processes described above.

Accordingly, the present disclosure teaches subtractive methods, additive methods, and hybrid additive/subtractive methods of forming a compact phased array antenna. The subtractive method includes milling a plurality of antenna elements in a multilayer printed circuit board (PCB) structure, the multilayer PCB structure including a base dielectric layer and a plurality of stacked dielectric layers laminated together to form a unitary structure; using via holes to transition RF energy between the feed network and the feed network elements; and depositing conductive material on the dielectric to create impedance matched antenna elements and transmission line networks dielectric to create impedance matched elements and transmission line networks. The additive method includes the depositing of successive layers of conductive or dielectric material in order to create antenna elements, transmission lines, impedance matching features and structural bodies to form a phased array antenna. The dielectric is varied to allow the effective dielectric constant to be manipulated, thus allowing impedance matching to be optimized throughout the system, including between the device and free space. The third method outlined is a hybrid of the additive and subtractive methods, allowing for advantages of both technologies to be utilized. The additive method includes the depositing of successive layers of conductive or dielectric material in order to create antenna elements, transmission lines, impedance matching features and structural bodies to form a phased array antenna. The dielectric is varied to allow the effective dielectric constant to be manipulated, thus allowing impedance matching to be optimized throughout the system, including between the device and free space. The third method outlined is a hybrid of the additive and subtractive methods, allowing for advantages of both technologies to be utilized.

In one embodiment, the present disclosure provides a method of forming a compact phased array antenna that includes milling a plurality of spaced-apart antenna elements by removing material of a multilayer printed circuit board (PCB) structure, the multilayer PCB structure including a base dielectric layer and a plurality of stacked dielectric layers laminated together to form a unitary structure; forming a plurality of via holes in the base dielectric layer and adjacent the antenna elements; and depositing conductive material on the base dielectric layer and antenna elements.

In another embodiment, the present disclosure provides a method of forming a compact phased array antenna that includes depositing a conductive material; depositing a base dielectric layer on the conductive material, the base dielectric layer comprising at least one dielectric material; forming via holes in the base dielectric layer by controlling the deposition of the at least one dielectric material; depositing the conductive material in the via holes formed in the base dielectric layer; forming a plurality of antenna elements on the base dielectric layer using the at least one dielectric material; and depositing the conductive material on the antenna elements.

In another embodiment, the present disclosure provides A method of forming a compact phased array antenna that includes milling a plurality of via holes through a PCB structure; the PCB structures having a conductive layer formed on a bottom surface thereof; depositing conductive material in the plurality of via holes; depositing the conductive material to form a copper pad on a tope surface of the PCB structure and over the via holes; depositing at least one dielectric on the top surface of the PCB structure and forming a plurality of antenna elements; and depositing the conductive material on the antenna elements.

As used in this application and in the claims, a list of items joined by the term “and/of” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

What is claimed:

1. A method of forming a compact phased array antenna, comprising:
milling a plurality of spaced-apart antenna elements by removing material of a multilayer printed circuit board (PCB) structure, the multilayer PCB structure including a base dielectric layer and a plurality of stacked dielectric layers laminated together to form a unitary structure;
forming a plurality of via holes in the base dielectric layer and adjacent the antenna elements; and
depositing conductive material on the base dielectric layer and antenna elements.

2. The method of claim 1, wherein the spaced-apart antenna elements are each formed as pyramid structures by milling the stacked dielectric layers to the base layer.

3. The method of claim 1, wherein the antenna elements are each formed as domed structures by milling the stacked dielectric layers to the base layer.

4. The method of claim 1, further comprising:
depositing conductive material in the via holes to electrically couple the via holes to the conductive material on the base dielectric layer and at least one antenna element; and wherein the multilayer PCB structure includes a conductive layer on a side opposing the antenna elements.

5. The method of claim 4, further comprising:
removing the conductive material on the base dielectric layer from between the antenna elements.

6. A method of forming a compact phased array antenna, comprising:
depositing a conductive material;
depositing a base dielectric layer on the conductive material, the base dielectric layer comprising at least one dielectric material;
forming via holes in the base dielectric layer by controlling the deposition of the at least one dielectric material;
depositing the conductive material in the via holes formed in the base dielectric layer;
forming a plurality of antenna elements on the base dielectric layer using the at least one dielectric material; and
depositing the conductive material on the antenna elements.

7. The method of claim 6, wherein the antenna elements are formed to have a dielectric constant gradient using two or more dielectric materials.

8. The method of claim 6, wherein the base layer is formed to have a dielectric constant gradient.

9. The method of claim 6, wherein the antenna elements are each formed as pyramid structures by milling the stacked dielectric layers to the base dielectric layer.

10. The method of claim 6, wherein the antenna elements are each formed as domed structures by milling the stacked dielectric layers to the base dielectric layer.

11. The method of claim 6, further comprising:
depositing at least one dielectric material between the antenna elements to form dielectric lensing structure between each antenna element.

12. The method of claim 11, further comprising:
removing a portion of the dielectric material deposited between the antenna elements.

13. The method of claim 11, wherein dielectric material deposited between the antenna elements is formed to have a dielectric constant gradient using two or more dielectric materials.

14. The method of claim 6, wherein the antenna elements are formed to have a dielectric constant gradient using two or more dielectric materials and air.

15. A method of forming a compact phased array antenna, comprising:
milling a plurality of via holes through a PCB structure; the PCB structures having a conductive layer formed on a bottom surface thereof;
depositing conductive material in the plurality of via holes;
depositing the conductive material to form a copper pad on a tope surface of the PCB structure and over the via holes;
depositing at least one dielectric on the top surface of the PCB structure and forming a plurality of antenna elements; and
depositing the conductive material on the antenna elements.

16. The method of claim 15, wherein the antenna elements are formed to have a dielectric constant gradient using two or more dielectric materials.

17. The method of claim 15, wherein the base layer is formed to have a dielectric constant gradient.

18. The method of claim 15, wherein the antenna elements are each formed as pyramid structures by milling the stacked dielectric layers to the base dielectric layer.

19. The method of claim 15, wherein the antenna elements are each formed as domed structures by milling the stacked dielectric layers to the base dielectric layer.

20. The method of claim 15, further comprising:
depositing at least one dielectric material between the antenna elements to form dielectric lensing structure between each antenna element.

21. The method of claim 20, further comprising:
removing a portion of the dielectric material deposited between the antenna elements.

22. The method of claim 20, wherein dielectric material deposited between the antenna elements is formed to have a dielectric constant gradient using two or more dielectric materials.

23. The method of claim 15, wherein the antenna elements are formed to have a dielectric constant gradient using two or more dielectric materials and air.
